(19) United States
(12) Patent Application Publication
(10) Pub. No.: US 2015/0351247 A1
(43) Pub. Date: Dec. 3, 2015

(54) PACKAGE BOARD AND METHOD FOR MANUFACTURING THE SAME

(71) Applicant: SAMSUNG ELECTRO-MECHANICS CO., LTD., Suwon-Si (KR)

(72) Inventors: Kwang Hee KWON, Suwon-Si (KR); Myung Sam KANG, Suwon-Si (KR); Seung Eun LEE, Suwon-Si (KR); Ju Hee PARK, Suwon-Si (KR); Seung Yeop KOOK, Suwon-Si (KR); Je Gwang YOO, Suwon-Si (KR); Jin Seon PARK, Suwon-Si (KR)

(73) Assignee: SAMSUNG ELECTRO-MECHANICS CO., LTD., Suwon-Si, Gyeonggi-Do (KR)

(21) Appl. No.: 14/703,856

(22) Filed: May 4, 2015

(30) Foreign Application Priority Data
May 30, 2014 (KR) 10-2014-0066390

(51) Int. Cl. H05K 1/18; H05K 1/02; H05K 3/42; H05K 3/46; H05K 1/11; H05K 3/32

(52) U.S. Cl. CPC H05K 1/186; H05K 1/115; H05K 1/181; H05K 3/32; H05K 3/429; H05K 3/4644; H05K 1/0298; H05K 1/111; H05K 2201/10015

(57) ABSTRACT

There are provided a package board and a method for manufacturing the same. According to an exemplary embodiment of the present disclosure, the package board includes: a first insulating layer formed with a penetrating cavity; a capacitor disposed in the cavity and including a first electrode, a second electrode formed on the first electrode, and a dielectric layer formed between the first electrode and the second electrode; a second insulating layer formed on the first insulating layer and in the cavity to embed the capacitor; circuit layers formed on the first insulating layer and the second insulating layer; and a via penetrating through the second insulating layer to electrically connect the circuit layer to the capacitor.

### CROSS-REFERENCE TO RELATED APPLICATION

This application claims the foreign priority benefit of Korean Patent Application No. 10-2014-0066390, filed on May 30, 2014, entitled “Package Board And Method For Manufacturing The Same” which is hereby incorporated by reference in its entirety into this application.

### BACKGROUND

Embodiments of the present invention relate to a package board and a method for manufacturing the same.

With the rapid development of a semiconductor technology, a semiconductor device is remarkably growing. Further, the development for a semiconductor package such as a system in package (SIP), a chip sized package (CSP), and a flip chip package (FCP) configured as a package by mounting electronic devices such as the semiconductor device on a printed circuit board in advance has been actively conducted. Further, to improve miniaturization and performance of a high-performance smart phone, there is a package on package (POP) in which a control device and a memory device are implemented as one package form. The package on package may be implemented by individually packaging the control device and the memory device and stacking and connecting them.

### RELATED ART DOCUMENT

### Patent Document

(Patent Document 1) U.S. Pat. No. 5,986,209

### SUMMARY

An aspect of the present disclosure may provide a package board and a method for manufacturing a package board capable of shielding occurrence of signal noise due to an increase in an operating speed of a semiconductor device.

Another aspect of the present disclosure may provide a package board and a method for manufacturing a package board capable of improving signal transmission efficiency to a semiconductor device or external components.

According to an aspect of the present disclosure, a package board may include: a first insulating layer formed with a penetrating cavity; a capacitor disposed in the cavity and including a first electrode, a second electrode formed on the first electrode, and a dielectric layer formed between the first electrode and the second electrode; a second insulating layer formed on the first insulating layer and in the cavity to embed the capacitor; circuit layers formed on the first insulating layer and the second insulating layer; and a via penetrating through the second insulating layer to electrically connect the circuit layer to the capacitor.

According to another aspect of the present disclosure, a method for manufacturing a package board may include: preparing a board which includes a first insulating layer including a penetrating cavity and a first circuit layer formed on the first insulating layer; disposing a capacitor including a first electrode, a second electrode formed on the first electrode, and a dielectric layer formed between the first electrode and the second electrode in the cavity; forming a second insulating layer on the first insulating layer and in the cavity to embed the capacitor; forming a via penetrating through the second insulating layer and electrically connected to the capacitor; and forming a second circuit layer on the second insulating layer and forming a third circuit layer beneath the first insulating layer.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified diagram illustrating a package board according to an exemplary embodiment of the present disclosure;

FIG. 2 is an exemplified diagram illustrating a package board according to another exemplary embodiment of the present disclosure;

FIGS. 3 through 14 are exemplified diagrams illustrating a method for manufacturing a package board according to an exemplary embodiment of the present disclosure; and

FIGS. 15 through 18 are exemplified diagrams illustrating a method for manufacturing a package board according to another exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

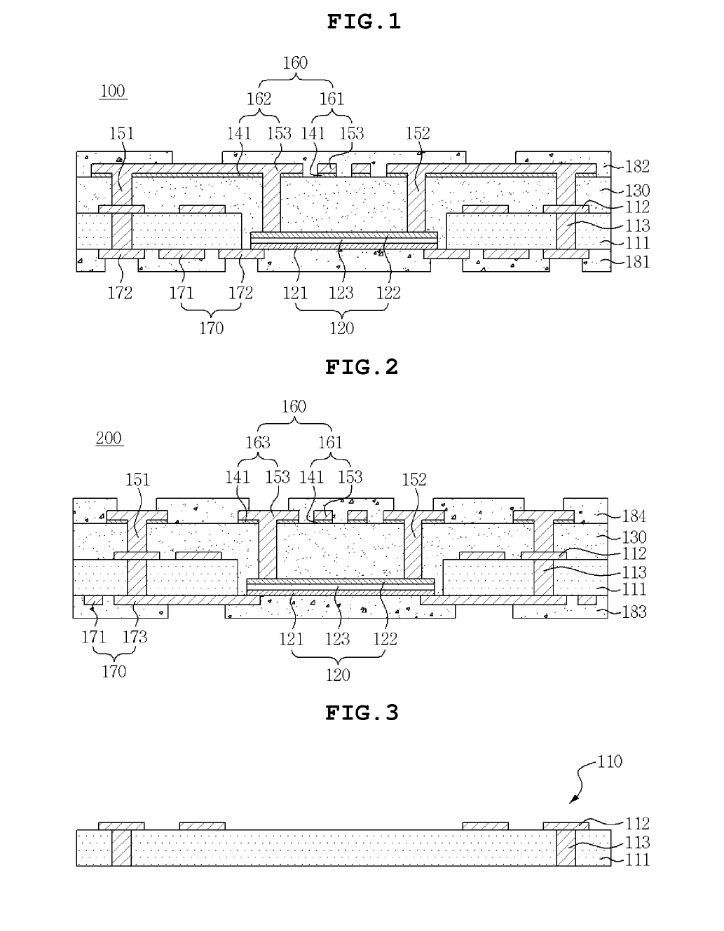

FIG. 1 is an exemplified diagram illustrating a package board according to an exemplary embodiment of the present disclosure.

Referring to FIG. 1, a package board 100 according to an exemplary embodiment of the present disclosure includes a first insulating layer 111, a second insulating layer 130, a capacitor 120, a first circuit layer 112 to a third circuit layer 170, a first via 113 to a third via 152, a first solder resist layer 181, and a second solder resistor layer 182.

According to the exemplary embodiment of the present disclosure, the first insulating layer 111 is made of a composite polymer resin which is generally used as an interlayer insulating material. For example, the first insulating layer 111 may be made of an epoxy based resin, such as prepreg, ajinomoto build up film (ABF), FR-4, and bismaleimide triazine (BT). However, according to the exemplary embodiment of the present disclosure, the material forming the first insulating layer 111 is not limited thereto. According to the exemplary embodiment of the present disclosure, the first insulating layer 111 may be selected from insulating materials known in the circuit board field.

According to the exemplary embodiment of the present disclosure, the first insulating layer 111 is provided with a cavity 114. The cavity 114 is formed to penetrate through the first insulating layer 111.

According to the exemplary embodiment of the present disclosure, the capacitor 120 is disposed in the cavity 114 of the first insulating layer 111. The capacitor 120 is the 3-layered thin film capacitor which includes the first electrode 121, the second electrode 122, and the dielectric layer 123. Here, the dielectric layer 123 is formed between the first electrode 121 and the second electrode 122. The first electrode 121 and the second electrode 122 are made of a conductive material.

According to the exemplary embodiment of the present disclosure, the first electrode 121 is formed to be exposed from a lower surface of the first insulating layer 111. Further, the first electrode 121 of the capacitor 120 is formed to be partially bonded to the third circuit layer 170. For example, when the first circuit layer 112 is the power layer, the first electrode 121 of the capacitor 120 may also serve as the power layer.

The package board 100 according to the exemplary embodiment of the present disclosure has the capacitor 120 embedded therein to shield noises of an electrical signal transmitted from the semiconductor device (not illustrated) which is mounted later. According to the exemplary embodiment of the present disclosure, the semiconductor device (not illustrated) mounted on the package board 100 may be a memory device.

According to the exemplary embodiment of the present disclosure, the second insulating layer 130 is formed on the first insulating layer 111. Further, the second insulating layer 130 is formed in the cavity 114 of the first insulating layer 114 to embed the capacitor 120. According to the exemplary embodiment of the present disclosure, the second insulating layer 130 is made of the composite polymer resin which is generally used as an interlayer insulating material. For example, the second insulating layer 130 may be made of an epoxy based resin, such as prepreg, ajinomoto build up film (ABF), FR-4, and bismaleimide triazine (BT). However, according to the exemplary embodiment of the present disclosure, the material forming the second insulating layer 130 is not limited thereto. According to the exemplary embodiment of the present disclosure, the second insulating layer 130 may be selected from the insulating materials known in the circuit board field.

According to the exemplary embodiment of the present disclosure, the first circuit layer 112 is formed on the first insulating layer 111.

According to the exemplary embodiment of the present disclosure, the second circuit layer 160 is formed on the second insulating layer 130. Further, the second circuit layer 160 includes a second circuit pattern 161 and a bonding pad 162. When the semiconductor device (not illustrated) is mounted on the package board 100, the bonding pad 162 is electrically connected to the semiconductor device. For example, the bonding pad 162 is electrically connected to the semiconductor device (not illustrated) through a wire.

According to the exemplary embodiment of the present disclosure, a third circuit layer 170 is formed beneath the first insulating layer 111. The third circuit layer 170 includes a third circuit pattern 171 and an external connection pad 172. The external connection pad 172 is electrically connected to external components. For example, the external components may be a semiconductor package, a package board, and the like. According to the exemplary embodiment of the present disclosure, the external connection pad 172 is bonded to the first electrode 121 of the capacitor 120 and thus is electrically connected thereto. As such, the external connection pad 172 is directly electrically connected to the capacitor 120, which is a signal transmission distance between the capacitor 120 and the external components (not illustrated) is shortened. Therefore, in the package board 100 according to the exemplary embodiment of the present disclosure, such that the signal transmission efficiency between the external components (not illustrated) is improved.

The exemplary embodiment of the present disclosure describes, by way of example, that the external connection pad 172 is bonded to the capacitor 120. However, the present disclosure is not limited to a structure in which the external connection pad 172 is bonded to the capacitor 120. That is, the third circuit pattern 171 may be bonded to the capacitor 120 according to the selection of those skilled in the art.

According to the exemplary embodiment of the present disclosure, the first circuit layer 112 to the third circuit layer 170 are made of the conductive material. For example, the first circuit layer 112 to the third circuit layer 170 are made of copper (Cu). However, the material forming the first circuit layer 112 to the third circuit layer 170 is not limited to copper. That is, any material which may be used as a conductive material for a circuit in a circuit board field may be applied to the first circuit layer 112 to the third circuit layer 170 without being limited.

Further, according to the exemplary embodiment of the present disclosure, one of the first circuit layer 112 to the third circuit layer 170 may be a power layer and the other thereof may be a ground layer.

According to the exemplary embodiment of the present disclosure, the first via 113 is formed on the first insulating layer 111. The first via 113 is formed to penetrate through the first insulating layer 111 to electrically connect the first circuit layer 112 to the third circuit layer 170.

According to the exemplary embodiment of the present disclosure, the second via 151 is formed on the second insulating layer 130. The second via 151 is formed to penetrate through the second insulating layer 130 to electrically connect the first circuit layer 112 to the second circuit layer 160.

According to the exemplary embodiment of the present disclosure, the third via 152 is formed on the second insulating layer 130. The third via 152 is formed to penetrate through the second insulating layer 130 to electrically connect the second circuit layer 160 to the capacitor 120. For example, the third via 152 is bonded to the second circuit layer 160 and the second electrode 122 of the capacitor 120, respectively.

According to the exemplary embodiment of the present disclosure, the first via 113 to the third via 152 are made of a conductive material for a via used in a circuit board field.

According to the exemplary embodiment of the present disclosure, the first solder resist layer 181 is formed beneath the first insulating layer 111. The first solder resist layer 181 is formed to enclose the third circuit layer 170 except for an area connected to the outside. The so formed first solder resist layer 181 protects the first electrode 121 of the capacitor 120 which is exposed from the first insulating layer 111. That is, the first solder resist layer 181 is formed to enclose the third circuit pattern 171 and the capacitor 120 and is formed to expose the external connection pad 172.

According to the exemplary embodiment of the present disclosure, the second solder resist layer 182 is formed on the second insulating layer 130. The second solder resist layer 182 encloses the second circuit pattern 161 and is formed to expose the bonding pad 162.

According to the exemplary embodiment of the present disclosure, the first solder resist layer 181 and the second solder resist layer 182 protect the circuit patterns from soldering in soldering process which connects the semiconductor device or the external components to the package board 100. Further, the first solder resist layer 181 and the second solder resist layer 182 prevent the circuit patterns from being oxidized. The first solder resist layer 181 and the second solder resist layer 182 are made of a heat resistant covering material.

FIG. 2 is an exemplified diagram illustrating a package board according to another exemplary embodiment of the present disclosure.

Referring to FIG. 2, a package board 200 according to the exemplary embodiment of the present disclosure includes a first insulating layer 111, a second insulating layer 130, a capacitor 120, a first circuit layer 112 to a third circuit layer 170, a first via 113 to a third via 152, a first solder resist layer 183, and a second solder resistor layer 184.

According to the exemplary embodiment of the present disclosure, the first insulating layer 111 is provided with a cavity 114. The cavity 114 is formed to penetrate through the first insulating layer 111. The capacitor 120 is disposed in the cavity 114.

According to the exemplary embodiment of the present disclosure, the second insulating layer 130 is formed on the first insulating layer 111. Further, the second insulating layer 130 is formed in the cavity 114 of the first insulating layer 114 to embed the capacitor 120.

According to the exemplary embodiment of the present disclosure, the first insulating layer 111 and the second insulating layer 130 are generally made of a composite polymer resin used as an interlayer insulating material.

According to the exemplary embodiment of the present disclosure, the capacitor 120 is disposed in the cavity 114 of the first insulating layer 111. The capacitor 120 is the 3-layered thin film capacitor which includes the first electrode 121, the second electrode 122, and the dielectric layer 123. Here, the dielectric layer 123 is formed between the first electrode 121 and the second electrode 122. The first electrode 121 and the second electrode 122 are made of a conductive material.

According to the exemplary embodiment of the present disclosure, the first electrode 121 is formed to be exposed from a lower surface of the first insulating layer 111. Further, the first electrode 121 of the capacitor 120 is formed to be partially bonded to the third circuit layer 170. For example, when the first circuit layer 112 is the power layer, the first electrode 121 of the capacitor 120 may also serve as the power layer.

The package board 200 according to the exemplary embodiment of the present disclosure has the capacitor 120 embedded therein to shield noises of an electrical signal transmitted from the semiconductor device (not illustrated) which is mounted later. According to the exemplary embodiment of the present disclosure, the semiconductor device (not illustrated) mounted on the package board 200 may be a memory device.

According to the exemplary embodiment of the present disclosure, the first circuit layer 112 is formed on the first insulating layer 111.

According to the exemplary embodiment of the present disclosure, the second circuit layer 160 is formed on the second insulating layer 130. Further, the second circuit layer 160 includes the second circuit pattern 161 and the external connection pad 163. The external connection pad 163 is electrically connected to external components. For example, the external components may be a semiconductor package, a package board, and the like.

According to the exemplary embodiment of the present disclosure, the third circuit layer 170 is formed beneath the first insulating layer 111. The third circuit layer 170 includes the third circuit pattern 171 and the bonding pad 173. When the semiconductor device (not illustrated) is mounted on the package board 200, the bonding pad 173 is electrically connected to the semiconductor device. For example, the bonding pad 173 is electrically connected to the semiconductor device (not illustrated) through a wire. According to the exemplary embodiment of the present disclosure, a portion of the bonding pad 173 is bonded to the first electrode 121 and thus is electrically connected thereto.

As such, the bonding pad 173 is directly electrically connected to the capacitor 120, such that a signal transmission distance between the semiconductor device (not illustrated) and the capacitor 120 is shortened. Therefore, in the package board 200 according to the exemplary embodiment of the present disclosure, the signal transmission efficiency to the semiconductor device (not illustrated) is improved.

The exemplary embodiment of the present disclosure describes, by way of example, that the bonding pad 173 is bonded to the capacitor 120. However, the present disclosure is not limited to a structure in which the bonding pad 173 is bonded to the capacitor 120. That is, the third circuit pattern 171 may be bonded to the capacitor 120 according to the selection of those skilled in the art.

Any material which may be used as a conductive material for a circuit in a circuit board field may be applied to the first circuit layer 112 to the third circuit layer 170 according to the exemplary embodiment of the present disclosure without being limited. Further, according to the exemplary embodiment of the present disclosure, one of the first circuit layer 112 to the third circuit layer 170 may be a power layer and the other thereof may be a ground layer.

According to the exemplary embodiment of the present disclosure, the first via 113 is formed on the first insulating layer 111. The first via 113 is formed to penetrate through the first insulating layer 111 to electrically connect the first circuit layer 112 to the third circuit layer 170.

According to the exemplary embodiment of the present disclosure, the second via 151 is formed on the second insulating layer 130. The second via 151 is formed to penetrate through the second insulating layer 130 to electrically connect the first circuit layer 112 to the second circuit layer 160.

According to the exemplary embodiment of the present disclosure, the third via 152 is formed on the second insulating layer 130. The third via 152 is formed to penetrate through the second insulating layer 130 to electrically connect the second circuit layer 160 to the capacitor 120. For example, the second via 151 is bonded to the second circuit layer 160 and the second electrode 122 of the capacitor 120, respectively.

According to the exemplary embodiment of the present disclosure, the first via 113 to the third via 152 are made of a conductive material for a via used in a circuit board field.

According to the exemplary embodiment of the present disclosure, the first solder resist layer 183 is formed beneath the first insulating layer 111. The first solder resist layer 183 is formed to enclose the third circuit layer 170 and the first electrode 121 of the capacitor 120. In this case, the first solder resist layer 183 is formed to partially expose the bonding pad 162.

According to the exemplary embodiment of the present disclosure, the second solder resist layer 184 is formed on the second insulating layer 130. The second solder resist layer 184 encloses the second circuit pattern 161 and is formed to expose the external connection pad 172.

According to the exemplary embodiment of the present disclosure, the first solder resist layer 183 and the second solder resist layer 184 protect the circuit patterns from soldering in soldering process. Further, the first solder resist layer 183 and the second solder resist layer 184 prevent the circuit patterns from being oxidized. The first solder resist layer 183 and the second solder resist layer 184 are made of the heat resistant covering material.

FIGS. 3 through 14 are exemplified diagrams illustrating a method for manufacturing a package board according to an exemplary embodiment of the present disclosure.

Referring to FIG. 3, the board 110 is provided.

According to the exemplary embodiment of the present disclosure, the board 110 includes the first insulating layer 111, the first circuit layer 112, and the first via 113.

According to the exemplary embodiment of the present disclosure, the first insulating layer 111 is made of a composite polymer resin which is generally used as an interlayer insulating material. For example, the first insulating layer 111 may be made of the epoxy based resin, such as prepreg, ajinomoto build up film (ABF), FR-4, and bismaleimide triazine (BT). However, according to the exemplary embodiment of the present disclosure, the material forming the first insulating layer 111 is not limited thereto. According to the exemplary embodiment of the present disclosure, the first insulating layer 111 may be selected from insulating materials known in the circuit board field.

According to the exemplary embodiment of the present disclosure, the first circuit layer 112 is formed on the first insulating layer 111.

According to the exemplary embodiment of the present disclosure, the first via 113 is formed to penetrate through the first insulating layer 111. Further, according to the exemplary embodiment of the present disclosure, the upper portion of the first via 113 is bonded to the first circuit layer 112.

According to the exemplary embodiment of the present disclosure, the first circuit layer 112 and the first via 113 are made of the conductive material used in the circuit board field. Further, as a method for forming a first circuit layer 112 and a first via 113 on a first insulating layer 111, any method for forming circuit patterns and vias known in the circuit board field may also be applied.

The exemplary embodiment of the present disclosure describes, by way of example, that the circuit layer is formed only on the first insulating layer 111, but is not limited thereto. For example, the board 110 may be the first insulating layer 111 on which the circuit layer is not formed.

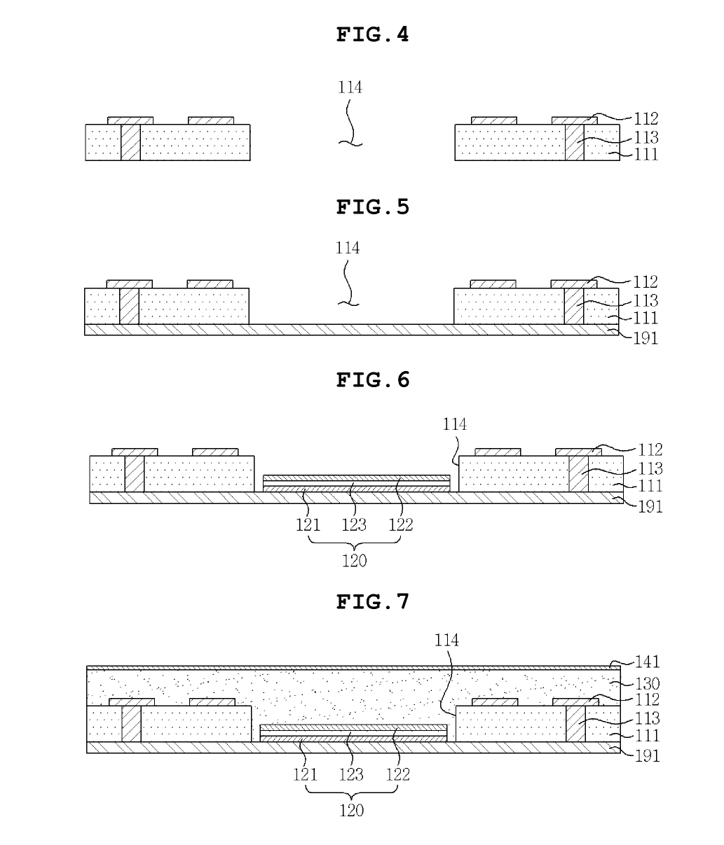

Referring to FIG. 4, the first insulating layer 111 is provided with the cavity 114.

According to the exemplary embodiment of the present disclosure, the cavity 114 is formed to penetrate through the first insulating layer 111. The cavity 114 is formed in an area in which the capacitor (not illustrated) will be disposed later. For example, the cavity 114 may be formed using a laser drill. However, a method for forming a cavity 114 is not limited thereto and therefore any method used in the circuit board field may be applied.

Referring to FIG. 5, a carrier film 191 is formed.

According to the exemplary embodiment of the present disclosure, the carrier film 190 is formed beneath the first insulating layer 111. Therefore, a lower portion of the cavity 114 is closed by the carrier film 191.

Referring to FIG. 6, the capacitor 120 is disposed.

According to the exemplary embodiment of the present disclosure, the capacitor 120 is disposed in the cavity 114. In this case, the capacitor 120 is fixed to be disposed in the cavity 114 by the carrier film 191 which is disposed beneath the cavity 114.

According to the exemplary embodiment of the present disclosure, the capacitor 120 is the 3-layered thin film capacitor which includes the first electrode 121, the second electrode 122, and the dielectric layer 123. Here, the dielectric layer 123 is formed between the first electrode 121 and the second electrode 122. The first electrode 121 and the second electrode 122 are made of the conductive material.

Referring to FIG. 7, the second insulating layer 130 and a first metal layer 141 are formed.

According to the exemplary embodiment of the present disclosure, the second insulating layer 130 is formed on the first insulating layer 111. Further, the second insulating layer 130 is also formed in the cavity 114 of the first insulating layer 111 to embed the capacitor 120.

For example, the second insulating layer 130 is stacked in high temperature and pressure and thus is formed on the first insulating layer 111 and in the cavity 114.

According to the exemplary embodiment of the present disclosure, the second insulating layer 130 is made of the composite polymer resin which is generally used as the interlayer insulating material. For example, the second insulating layer 130 may be made of an epoxy based resin, such as prepreg, ajinomoto build up film (ABF), FR-4, and bismaleimide triazine (BT). However, according to the exemplary embodiment of the present disclosure, the material forming the second insulating layer 130 is not limited thereto. According to the exemplary embodiment of the present disclosure, the second insulating layer 130 may be selected from the insulating materials known in the circuit board field.

According to the exemplary embodiment of the present disclosure, the first metal layer 141 is formed on the second insulating layer 130. For example, the first metal layer 141 are made of copper. However, the material of the first metal layer is not limited to copper, and therefore any material which may be used as the conductive material for the circuit in the circuit board field may be applied to the first metal layer without being limited.

According to the exemplary embodiment of the present disclosure, the first metal layer 141 may be formed by at least one of an electroless plating method and an electroplating method. Alternatively, the first metal layer 141 may be formed by a lamination method. A method for forming a first metal layer 141 is not limited to the foregoing method, and therefore any method which may form the metal layer on the insulating layer in the circuit board field may also be applied.

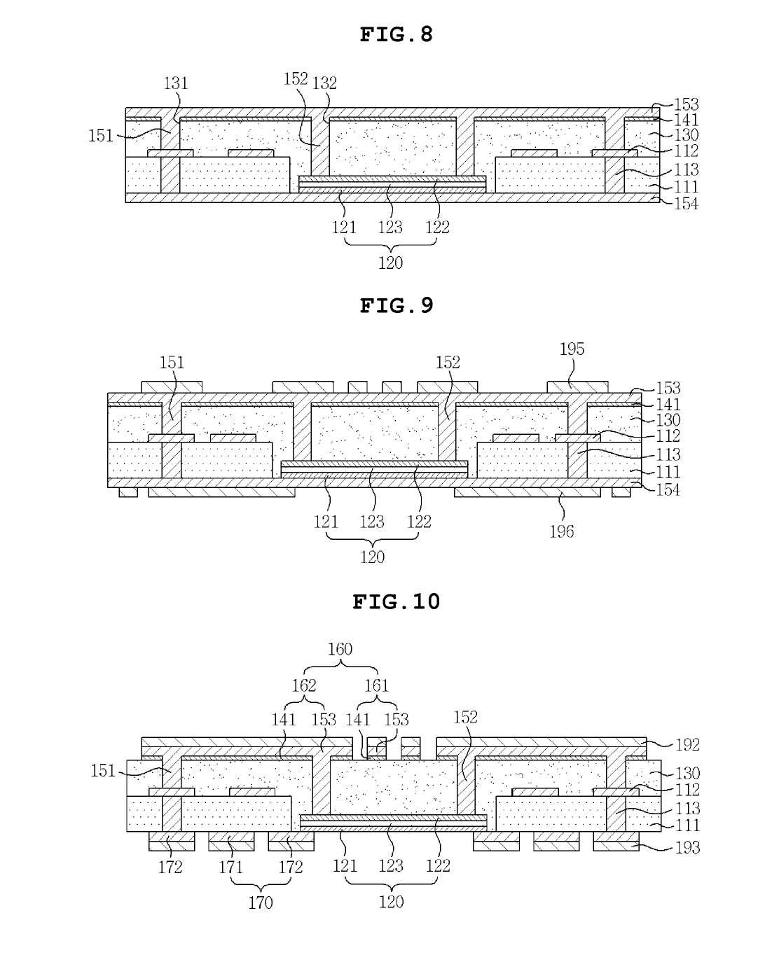

Referring to FIG. 8, the carrier film 191 is removed.

According to the exemplary embodiment of the present disclosure, when the carrier film 191 is removed, the first electrode 121 of the capacitor 120 is exposed to the outside.

Referring to FIG. 9, a second via hole 131 and a third via hole 132 are formed.

According to the exemplary embodiment of the present disclosure, the second via hole 131 is formed to penetrate through the second insulating layer 130. In this case, the second via hole 131 is formed to expose the upper portion of the first circuit layer 112.

According to the exemplary embodiment of the present disclosure, a third via hole 132 is formed to penetrate through the second insulating layer 130. In this case, the third via hole 132 is formed to expose the second electrode 122 of the capacitor 120.

Here, the second via hole 131 and the third via hole 132 are formed by a method of forming a via hole which is used in the circuit board field. For example, the second via hole 131 and the third via hole 132 are formed by the laser drill.

Referring to FIG. 10, a second via 151 and a third via 152 are formed.

According to the exemplary embodiment of the present disclosure, the second via 151 is formed by filling the second via hole 131 with the conductive material. Therefore, the second via 151 is formed to penetrate through the second insulating layer 130 and is electrically connected to the first circuit layer 112.

According to the exemplary embodiment of the present disclosure, the third via 152 is formed by filling the third via hole 132 with the conductive material. Therefore, the third via 152 is formed to penetrate through the second insulating layer 130 and is electrically connected to the second electrode 122 of the capacitor 120.

According to the exemplary embodiment of the present disclosure, when the second via 151 and the third via 152 are formed, a second metal layer 153 is formed on the first metal layer 141. Further, when the second via 151 and the third via 152 are formed, a third metal layer 154 is formed beneath the first insulating layer 111.

According to the exemplary embodiment of the present disclosure, the second metal layer 153 and the third metal layer 154 are simultaneously formed in the same process as the process for forming a second via 151 and a third via 152 or are separately formed by a separate process from the process for forming a second via 151 and a third via 152.

For example, the second via 151 and the third via 152 may be formed by the electroless plating process and the electroplating process. In this case, the second metal layer 153 and the third metal layer 154 are also simultaneously formed with the second via 151 and the third via 152.

Alternatively, the second via 151 and the third via 152 may be formed by a screen printing method using a conductive paste. In this case, after the second via 151 and the third via 152 are formed, the second metal layer 153 and the third metal layer 154 are formed by the separate electroless plating process and electroplating process.

According to the exemplary embodiment of the present disclosure, a method for forming a second via 151, a third via 152, a second metal layer 153, and a third metal layer 154 is not limited to the foregoing method. Further, according to the exemplary embodiment of the present disclosure, the first metal layer 141 and the second metal layer 153 both are formed, but one of the second metal layer 141 and the third metal layer 153 may be omitted according to the selection of those skilled in the art.

According to the exemplary embodiment of the present disclosure, the second via 151, the third via 152, the second metal layer 153, and the third metal layer 154 are made of a conductive material for a circuit such as copper.

According to the exemplary embodiment of the present disclosure, the capacitor 120 is connected to the plurality of third vias 152 to reduce reactance. Therefore, noise shielding characteristics against an electronic signal are improved.

According to the exemplary embodiment of the present disclosure, when the first via 113 is not formed in the board 110 (FIG. 3) of FIG. 3, the first via 113 is simultaneously formed with the second via 151 and the third via 152 in the present process. That is, in FIG. 9, after the first via hole (not illustrated) penetrating through the first insulating layer 111 is formed, in FIG. 10, the first via hole (not illustrated) is filled with the conductive material to form the first via 113.

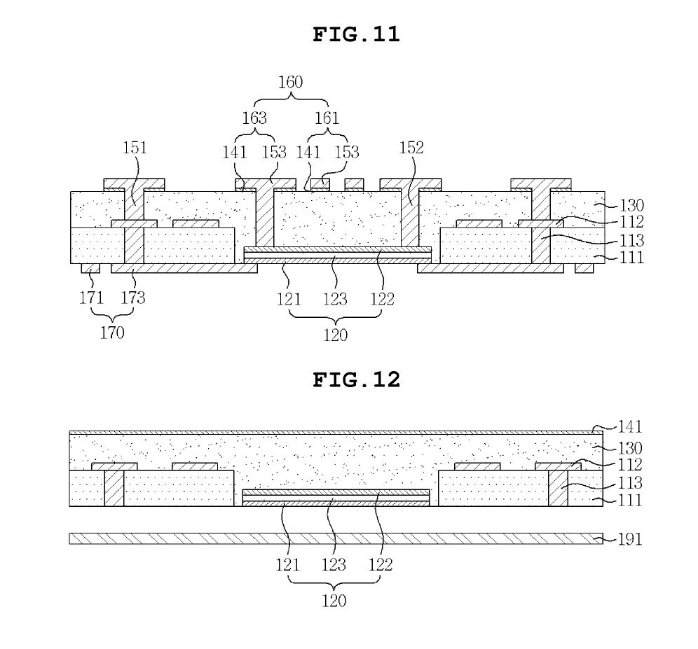

Referring to FIG. 11, a first etching resist 192 and a second etching resist 193 are formed.

According to the exemplary embodiment of the present disclosure, the first etching resist 192 is formed on the second metal layer 153. The first etching resist 192 is formed to protect an area in which the second circuit layer (not illustrated) will be formed and is formed to expose other areas.

According to the exemplary embodiment of the present disclosure, the second etching resist 193 is formed beneath the third metal layer 154. The second etching resist 193 is formed to protect an area in which the third circuit layer (not illustrated) will be formed and is formed to expose other areas.

Referring to FIG. 12, the second circuit layer 160 and the third circuit layer 170 are formed.

According to the exemplary embodiment of the present disclosure, the second metal layer 153 (FIG. 11) exposed by the first etching resist 192 is etched. In this case, the first metal layer 141 (FIG. 11) formed beneath the second metal layer 153 (FIG. 11) is simultaneously etched. As such, the second circuit layer 160 is formed by etching the second metal layer 153 (FIG. 11) and the first metal layer 141 (FIG. 11) which are exposed by the first etching resist 192.

According to the exemplary embodiment of the present disclosure, the second circuit layer 160 includes the second circuit pattern 161 and the bonding pad 162. When the semiconductor device (not illustrated) is mounted on the package board, the bonding pad 162 is electrically connected to the semiconductor device. Here, the semiconductor device (not illustrated) may be a memory device. Further, the second circuit layer 160 is formed on the second via 151 and the third via 152. Therefore, the second circuit layer 160 is electrically connected to the first circuit layer 112 and the capacitor 120 through the second via 151 and the third via 152.

Further, according to the exemplary embodiment of the present disclosure, the third metal layer 154 (FIG. 11) exposed by the second etching resist 193 is etched. As such, the third circuit layer 170 is formed by etching the third metal layer 154 (FIG. 11). According to the exemplary embodiment of the present disclosure, the third circuit layer 170 includes the third circuit pattern 171 and the external connection pad 172.

According to the exemplary embodiment of the present disclosure, the external connection pad 172 is electrically connected to the external components. For example, the external components may be a semiconductor package, a package board, and the like. The external connection pad 172 is bonded to the first electrode 121 of the capacitor 120 and thus is electrically connected thereto.

According to the exemplary embodiment of the present disclosure, the external connection pad 172 is directly electrically connected to the capacitor 120, such that the signal transmission distance between the capacitor 120 and the external components (not illustrated) is shortened. Therefore, in the package board 100 (FIG. 14) formed according to the exemplary embodiment of the present disclosure, the signal transmission efficiency between the external components (not illustrated) is improved.

Further, according to the exemplary embodiment of the present disclosure, the third circuit layer 170 is formed beneath the first via 113. Therefore, the third circuit layer 170 is electrically connected to the first circuit layer 112 through the first via 113.

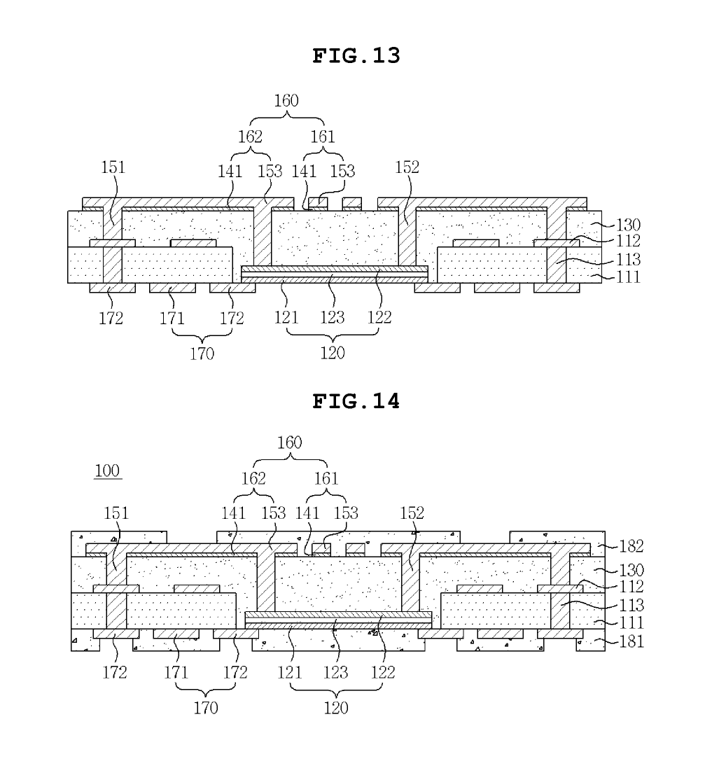

Referring to FIG. 13, the first etching resist 192 (FIG. 12) and the second etching resist 193 (FIG. 12) are removed.

Referring to FIG. 14, the first solder resist layer 181 and the second solder resist layer 182 are formed.

According to the exemplary embodiment of the present disclosure, the first solder resist layer 181 and the second solder resist layer 182 are formed to protect the second circuit layer 160 and the third circuit layer 170 from external environment. The first solder resist layer 181 and the second solder resist layer 182 are formed to prevent solder from applying on the circuit layer or the circuit layer from oxidizing while the external components are mounted on the package board 100.

According to the exemplary embodiment of the present disclosure, the first solder resist layer 181 is formed beneath the first insulating layer 111 to enclose the third circuit layer 170. In this case, the first solder resist layer 181 is formed to expose the external connection pad 172. Further, the second solder resist layer 182 is formed on the second insulating layer 130 to enclose the second circuit layer 160. In this case, the second solder resist layer 182 is formed to expose the bonding pad 162. According to the exemplary embodiment of the present disclosure, the first solder resist layer 181 and the second solder resist layer 182 are made of the heat resistant covering material.

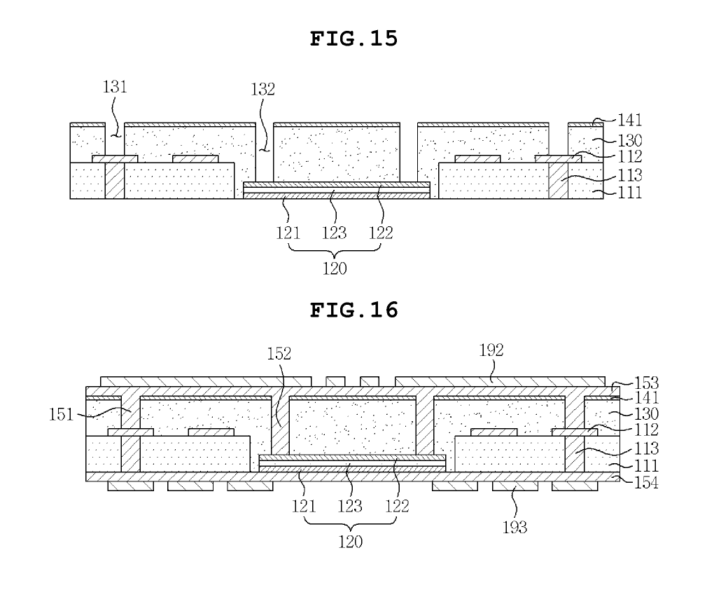

FIGS. 15 through 18 are exemplified diagrams illustrating a method for manufacturing a package board according to another exemplary embodiment of the present disclosure.

Referring to FIG. 15, a first etching resist 195 is formed on the second metal layer 153 and a second etching resist 196 is formed beneath the third metal layer 154.

Here, the detailed description of processes performed prior to forming the first etching resist 195 and the second etching resist 196 will refer to FIGS. 3 to 10.

According to the exemplary embodiment of the present disclosure, the first etching resist 195 is formed on the second metal layer 153. The first etching resist 195 is formed to protect an area in which the second circuit layer (not illustrated) will be formed and is formed to expose other areas.

According to the exemplary embodiment of the present disclosure, the second etching resist 196 is formed beneath the third metal layer 154. The second etching resist 196 is formed to protect an area in which the third circuit layer (not illustrated) will be formed and is formed to expose other areas.

Referring to FIG. 16, the second circuit layer 160 and the third circuit layer 170 are formed.

According to the exemplary embodiment of the present disclosure, the second metal layer 153 exposed by the first etching resist 195 is etched. In this case, the first metal layer 141 formed beneath the second metal layer 153 is also etched simultaneously. As such, the second circuit layer 160 is formed by etching the second metal layer 153 and the first metal layer 141 which are exposed by the first etching resist 195.

According to the exemplary embodiment of the present disclosure, the second circuit layer 160 includes the second circuit pattern 161 and the external connection pad 163. The external connection pad 163 is electrically connected to external components. For example, the external components may be a semiconductor package, a package board, and the like. Further, the second circuit layer 160 is formed on the second via 151 and the third via 152. Therefore, according to the exemplary embodiment of the present disclosure, the second circuit layer 160 is electrically connected to the first circuit layer 112 and the capacitor 120 through the second via 151 and the third via 152.

Further, according to the exemplary embodiment of the present disclosure, the third metal layer 154 exposed by the second etching resist 196 is etched. As such, the third circuit layer 170 is formed by etching the third metal layer 154 which are exposed by the second etching resist 196 According to the exemplary embodiment of the present disclosure, the third circuit layer 170 includes the third circuit pattern 171 and the bonding pad 173. When the semiconductor device (not illustrated) is mounted on the package board, the bonding pad 173 is electrically connected to the semiconductor device. The bonding pad 173 is bonded to the first electrode 121 of the capacitor 120 and thus is electrically connected thereto. Here, the semiconductor device (not illustrated) may be a memory device.

According to the exemplary embodiment of the present disclosure, the bonding pad 173 is directly electrically connected to the capacitor 120, such that a signal transmission distance between the semiconductor device (not illustrated) and the capacitor 120 is shortened. Therefore, in the package board 200 according to the exemplary embodiment of the present disclosure, the signal transmission efficiency to the semiconductor device (not illustrated) is improved.

Further, according to the exemplary embodiment of the present disclosure, the third circuit layer 170 is formed beneath the first via 113. Therefore, the third circuit layer 170 is electrically connected to the first circuit layer 112 through the first via 113.

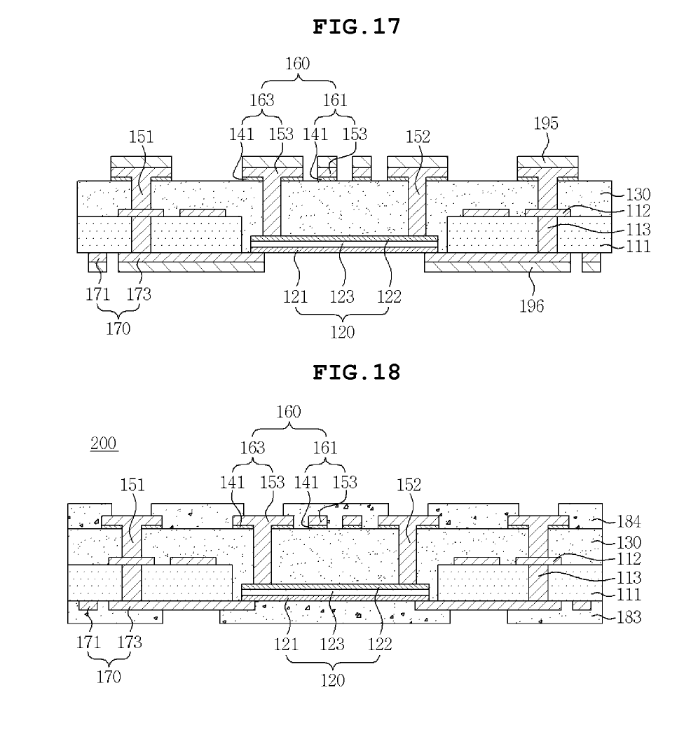

Referring to FIG. 17, the first etching resist 195 (FIG. 16) and the second etching resist 196 (FIG. 16) may be removed.

Referring to FIG. 18, the first solder resist layer 183 and the second solder resist layer 184 are formed.

According to the exemplary embodiment of the present disclosure, the first solder resist layer 183 and the second solder resist layer 184 are formed to protect the second circuit layer 160 and the third circuit layer 170 from external environment. The first solder resist layer 183 and the second solder resist layer 184 are formed to prevent solder from applying on the circuit layer or the circuit layer from oxidizing while the external components are mounted on the package board 200.

According to the exemplary embodiment of the present disclosure, the first solder resist layer 184 is formed beneath the first insulating layer 111 to enclose the third circuit layer 170. In this case, the first solder resist layer 183 is formed to expose the bonding pad 173.

Further, according to the exemplary embodiment of the present disclosure, the second solder resist layer 184 is formed on the second insulating layer 130 to enclose the second circuit layer 160. In this case, the second solder resist layer 184 is formed to expose the external connection pad 163.

According to the exemplary embodiment of the present disclosure, the first solder resist layer 183 and the second solder resist layer 184 are made of the heat resistant covering material.

The exemplary embodiment of the present disclosure describes, by way of example, that the package boards 100 and 200 are provided with the 2-layered insulating layer and the 3-layered circuit layer, but is not limited thereto. That is, the number of layers of the package boards 100 and 200 may be variously implemented according to the selection of those skilled in the art.

Further, according to the exemplary embodiment of the present disclosure, the circuit layer is formed by applying a tenting method. However, the method of forming a circuit layer is not limited to the tenting method. As the method of forming a circuit layer, any of the methods such as a semi-additive process (SAP) and a modify semi-additive process (MSAP) which may be applied in the circuit board filed may be applied.

Further, the semiconductor devices (not illustrated) mounted on the package board according to the exemplary embodiments of the present disclosure may be a memory device. That is, when being applied to a single semiconductor package or a stacked semiconductor package, the package board according to the exemplary embodiments of the present disclosure may be applied to the package in which the memory device is mounted. However, the semiconductor device mounted on the package board according to the exemplary embodiments of the present disclosure is not limited to the memory device.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A package board, comprising:
a first insulating layer formed with a penetrating cavity;
a capacitor disposed in the cavity and including a first electrode, a second electrode formed on the first electrode, and a dielectric layer formed between the first electrode and the second electrode;
a second insulating layer formed on the first insulating layer and in the cavity to embed the capacitor;
circuit layers formed on the first insulating layer and the second insulating layer; and
a via penetrating through the second insulating layer to electrically connect the circuit layer to the capacitor.

2. The package board of claim 1, wherein the circuit layer includes:
a first circuit layer formed on the first insulating layer;
a second circuit layer formed on the second insulating layer; and
a third circuit layer formed beneath the first insulating layer;

3. The package board of claim 2, wherein the via electrically connects the second electrode to the third circuit layer.

4. The package board of claim 2, wherein the third circuit layer is bonded to the first electrode of the capacitor.

5. The package board of claim 4, wherein the second circuit layer further includes a bonding pad which is electrically connected to a semiconductor device and the third circuit layer further includes an external connection pad which is electrically connected to an external connection terminal.

6. The package board of claim 5, wherein the external connection terminal is bonded to the first electrode of the capacitor.

7. The package board of claim 4, wherein the second circuit layer further includes an external connection pad which is electrically connected to an external connection terminal and the third circuit layer further includes a bonding pad which is electrically connected to a semiconductor device.

8. The package board of claim 7, wherein the bonding pad is bonded to the first electrode of the capacitor.

9. The package board of claim 1, further comprising:
a solder resist layer formed on at least one of the first insulating layer and the second insulating layer to enclose the circuit layers and patterned to expose an area connected to the outside among the circuit layers.

10. A method for manufacturing a package board, the method comprising:
preparing a board which includes a first insulating layer including a penetrating cavity and a first circuit layer formed on the first insulating layer;
disposing a capacitor including a first electrode, a second electrode formed on the first electrode, and a dielectric layer formed between the first electrode and the second electrode in the cavity;
forming a second insulating layer on the first insulating layer and in the cavity to embed the capacitor
forming a via penetrating through the second insulating layer and electrically connected to the capacitor; and
forming a second circuit layer on the second insulating layer and forming a third circuit layer beneath the first insulating layer.

11. The method of claim 10, further comprising:
prior to the disposing the capacitor, forming a carrier film beneath the first insulating layer to close a lower portion of the cavity; and
after the forming of the second insulating layer, removing the carrier film.

12. The method of claim 10, wherein in the forming of the via, the via is formed to be bonded to the second electrode of the capacitor.

13. The method of claim 10, wherein in the forming of the second circuit layer and the third circuit layer, the third circuit layer is formed to be bonded to the first electrode of the capacitor.

14. The method of claim 13, wherein in the forming of the second circuit layer and the third circuit layer, the second circuit layer further includes a bonding pad which is electrically connected to a semiconductor device and the third circuit layer further includes an external connection pad which is electrically connected to an external connection terminal.

15. The method of claim 14, wherein in the forming of the second circuit layer and the third circuit layer, the external connection terminal is formed to be bonded to the first electrode of the capacitor.

16. The method of claim 13, wherein in the forming of the second circuit layer and the third circuit layer, the second circuit layer further includes an external connection pad which is electrically connected to an external connection terminal and the third circuit layer further includes a bonding pad which is electrically connected to a semiconductor device.

17. The method of claim 16, wherein in the forming of the second circuit layer and the third circuit layer, the bonding pad is formed to be bonded to the first electrode of the capacitor.

18. The method of claim 10, further comprising:
after the forming of the second circuit layer and the third circuit layer, forming a first solder resist layer formed on the second insulating layer and patterned to expose an area connected to the outside in the second circuit layer; and
forming a second solder resist layer formed beneath the first insulating layer and patterned to expose an area connected to the outside in the third circuit layer.
